(19) United States
(12) Patent Application Publication
(10) Pub. No.: US 2009/0108443 A1
(43) Pub. Date: Apr. 30, 2009

(54) Flip-Chip Interconnect Structure

(75) Inventor: Hunt Hang Jiang, San Jose, CA (US)

Correspondence Address: FISH & RICHARDSON, PC, P.O. BOX 1022, MINNEAPOLIS, MN, 55440-1022, US

(73) Assignee: Monolithic Power Systems, Inc.

(21) Appl. No.: 11/928,218

(22) Filed: Oct. 30, 2007

(51) Int. Cl. H01L 23/488; H01L 21/44

(52) U.S. Cl. 257/737; 438/614; 257/E23.023; 257/E21.476

(57) ABSTRACT

Various aspects can be implemented for providing flip-chip interconnect structures for connecting or mounting semiconductor chips to supporting substrates, such as cards, circuit boards, carriers, lead frames, and the like. In general, one aspect can be a method of providing a flip-chip interconnect structure that includes providing a semiconductor work piece that includes one or more bond pads. The method also includes depositing a first non-reflowable layer that has a first melting temperature higher than a predetermined first reflow temperature. The method further includes depositing a reflowable stress relief layer that reflows at the predetermined first reflow temperature. The method additionally includes depositing a second non-reflowable layer that has a second melting temperature higher than the predetermined first reflow temperature such that the deposited reflowable stress relief layer is between the first and the second non-reflowable layers.

### TECHNICAL FIELD

This disclosure generally relates to flip-chip bonding, and specifically to flip-chip interconnect structures for connecting or mounting semiconductor work pieces, such as devices, dies, wafers, and chips (all hereinafter referred to generically as “semiconductor chips”), to supporting (e.g., packaging or interconnection) substrates, such as cards, circuit boards, carriers, lead frames, and the like.

### BACKGROUND

In contrast to wire bonding, which uses a face-up semiconductor chip having an electrical connection to each pad of the semiconductor chip through wires, flip-chip bonding uses a face-down semiconductor chip having an electrical connection to each pad of the semiconductor chip through conductive interconnects (e.g., a solder bump or a copper post). Besides semiconductor chips, flip-chip bonding can be used for other components, such as passive filters, detector arrays, and MEMs devices.

Thermally-induced mechanical stresses (e.g., shearing stress) in the flip-chip interconnect can develop from temperature fluctuations and differences in thermal expansion coefficients between the semiconductor chip and the supporting substrate during operation of the semiconductor chip. For example, when the semiconductor chip and the supporting substrate are exposed to elevated temperatures, they can expand at different rates and to different dimensions, thereby inducing mechanical stresses in the flip-chip interconnect.

To reduce the mechanical stresses, the semiconductor chip and supporting substrate are often constructed from materials having closely matched expansion coefficients so that they expand to substantially the same dimensions when exposed to an elevated temperature. Thermally-induced mechanical stresses, however, can still be generated each time the semiconductor chip is powered-up or turned-on. When the chip is powered-up or turned on, a large transient temperature difference between the chip and the supporting substrate can develop until the temperature of the supporting substrate reaches a temperature near that of the semiconductor work piece.

Because of the high temperatures and frequent power cycling (e.g., turning on and turning off) in high-performance semiconductor chips, flip-chip interconnects become mechanically and electrically unreliable even when the semiconductor chip and the supporting substrate have closely matched thermal expansion coefficients. This can become a greater problem for flip-chip assemblies as semiconductor chips are designed to dissipate more power in smaller volumes, thereby leading to greater thermally-induced mechanical stresses.

### SUMMARY

The present inventor recognized that flip-chip interconnect structures using elongated copper posts and methods for forming such structures can suffer from reliability problems associated with thermally-induced mechanical stresses developed at the bases or along the body of the interconnect structure. Consequently, the present inventor developed a flip-chip interconnect structure having a stress relief means and techniques for forming such a structure to alleviate the mechanical stresses and thereby improve the reliability of the flip-chip assembly.

The flip-chip interconnect structures disclosed herein can encompass various kinds of shapes. For example, the flip-chip interconnect structure can be in the form of a column (e.g., circular or rectangular), a post, or a pillar, or any other shape. Additionally, the flip-chip interconnect structure disclosed herein can include a non-reflowable base layer (e.g., a Cu or Ni metal layer) that contacts the bond pads (e.g., thru a seed layer such as Ti, TiW, or Cr) on the semiconductor chip, a non-reflowable body layer (e.g., a Cu or Ni metal layer), a reflowable stress relief layer (e.g., a Pb/Sn or Sn solder layer) between the non-reflowable base layer and the non-reflowable body layer (e.g., a Cu or Ni metal layer), and a reflowable fusing layer (e.g., a Pb/Sn or Sn solder layer) that contacts the interconnects on the interconnection or supporting substrate.

In general, one aspect can be a method of providing a flip-chip interconnect structure that includes providing a semiconductor work piece having one or more bond pads. The method also includes depositing a first non-reflowable layer that has a first melting temperature higher than a predetermined first reflow temperature. The method further includes depositing a reflowable stress relief layer that reflows at the predetermined first reflow temperature. The method additionally includes depositing a second non-reflowable layer that has a second melting temperature higher than the predetermined first reflow temperature such that the deposited reflowable stress relief layer is between the first and the second non-reflowable layers.

Another general aspect can be a flip-chip assembly that includes a semiconductor work piece and a plurality of interconnect structures connected to the semiconductor work piece. Each of the interconnect structures includes a first non-reflowable metal layer in contact with the semiconductor work piece. Each of the interconnect structures also includes a second non-reflowable metal layer and at least one reflowable stress relief layer that reflows at a predetermined first reflow temperature. The reflowable stress relief layer is between the first and the second non-reflowable metal layers.

Yet another general aspect can be a flip-chip assembly that includes a semiconductor work piece and a plurality of interconnect structures connected to the semiconductor work piece. Each of the interconnect structures includes a first non-reflowable metal layer in contact with the semiconductor work piece. Each of the interconnect structures also includes a second non-reflowable metal layer. Each of the interconnect structures further includes a means for providing stress relief to the interconnect structure.

These and other general aspects can optionally include one or more of the following specific aspects. For example, the method can include depositing a reflowable fusing layer that reflows at a predetermined second reflow temperature. The method can further include patterning a dielectric layer with openings for the one or more bond pads, and depositing a seed layer on each of the bond pads. Additionally, each of the interconnect structure can include a reflowable fusing layer that reflows at a predetermined second reflow temperature.

The predetermined first reflow temperature can be about 10 to 30 degrees higher than a melting temperature of the reflowable stress relief layer. The predetermined first reflow temperature can be the same as the predetermined second reflow temperature; for example, the stress relief layer and the fusing layer can include the same solder material. The predetermined first reflow temperature can be higher than the predetermined second reflow temperature, such that the reflowable stress relief layer does not reflow at the predetermined second reflow temperature.

The reflowable stress relief layer can be thicker than the reflowable fusing layer. The first non-reflowable layer can be above the seed layer. The first melting temperature can be the same as the second melting temperature; for example, both the first and second metal layers can include the same metal. The second non-reflowable metal layer can be thicker than the first non-reflowable metal layer. The first and second non-reflowable metal layers can each include copper, nickel, or tin. The reflowable stress relief layer can include either tin, indium, tin-lead alloy, tin-bismuth alloy, tin-copper alloy, tin-silver alloy, or tin-silver-copper alloy.

Particular aspects can be implemented to realize one or more of the following potential advantages. By having a stress relief means, such as one or more reflowable stress relief layers, as part of the flip-chip interconnect structure, the mechanical stresses developed at the bases or along the body of the interconnect structure can be reduced because the stress relief means can act as a shock absorber for the induced stresses. The flip-chip interconnect structure and techniques disclosed herein can have similar or better throughput as conventional interconnect structures and can be mass produced at low cost, comparatively speaking.

Additionally, the flip-chip interconnect structure and techniques disclosed herein can provide a more reliable and robust interconnect, when compared to an elongated copper-post flip-chip structure, by incorporating one or more stress relief layers (e.g., reflowable solders). For example, the effects of thermally-induced mechanical stresses can be reduced by having an interconnect structure with a large aspect ratio and stress relief means. Furthermore, when compared to the solder-bump flip-chip structure, the flip-chip interconnect structure and techniques disclosed herein can have controlled collapsible solder bumps without the use of solder dams to prevent solder overrun, better thermal conductivity because of the use of thermally conductive (e.g., copper) body layers, and do not require solder reflow at bump level prior to flip-chip assembly.

The general and specific aspects can be implemented using a system or method, or any appropriate combination of systems and methods. The details of one or more implementations are set forth in the accompanying drawings and the description below. Other features, aspects, and advantages will be apparent from the description, the drawings, and the claims.

### DESCRIPTION OF DRAWINGS

These and other aspects will now be described in detail with reference to the following drawings.

FIGS. 1A & B are cross-sectional diagrams of a flip-chip interconnect structure having a stress relief means disposed on a semiconductor chip.

FIGS. 1C & D are cross-sectional diagram showing a flip-chip interconnect structure between a semiconductor chip and a supporting substrate.

FIG. 2 is a flow chart showing an example process of providing a flip-chip interconnect structure having a stress relief means.

FIG. 3 is a cross-sectional diagram of a flip-chip interconnect structure having a stress relief means disposed on a supporting substrate.

Like reference symbols in the various drawings indicate like elements.

### DETAILED DESCRIPTION

In general, the examples described in this disclosure relate to flip-chip interconnect structures for electrically connecting semiconductor chips to supporting substrates and methods for constructing the flip-chip interconnect structures. The interconnect structure can serve several functions in the flip-chip assembly. Electrically, the interconnect structure can provide the conductive path from chip to supporting substrate. The interconnect structure can also provide a thermally conductive path to carry heat from the chip to the supporting substrate. In addition, the interconnect structure can provide part of or all of the mechanical mounting of the chip to the supporting substrate. Furthermore, the interconnect structure can function as a spacer, preventing electrical contact between the chip and conductors of the supporting substrate, and acting as a short lead to relieve mechanical stresses between die and substrate.

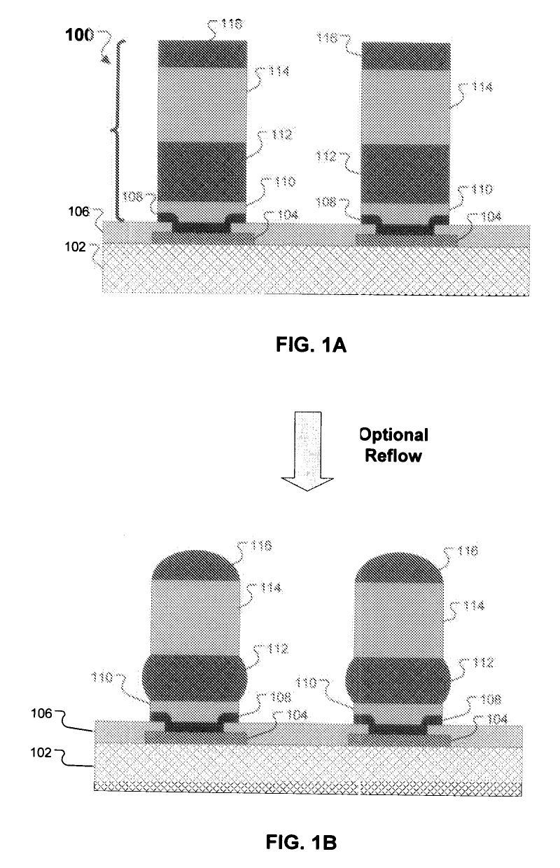

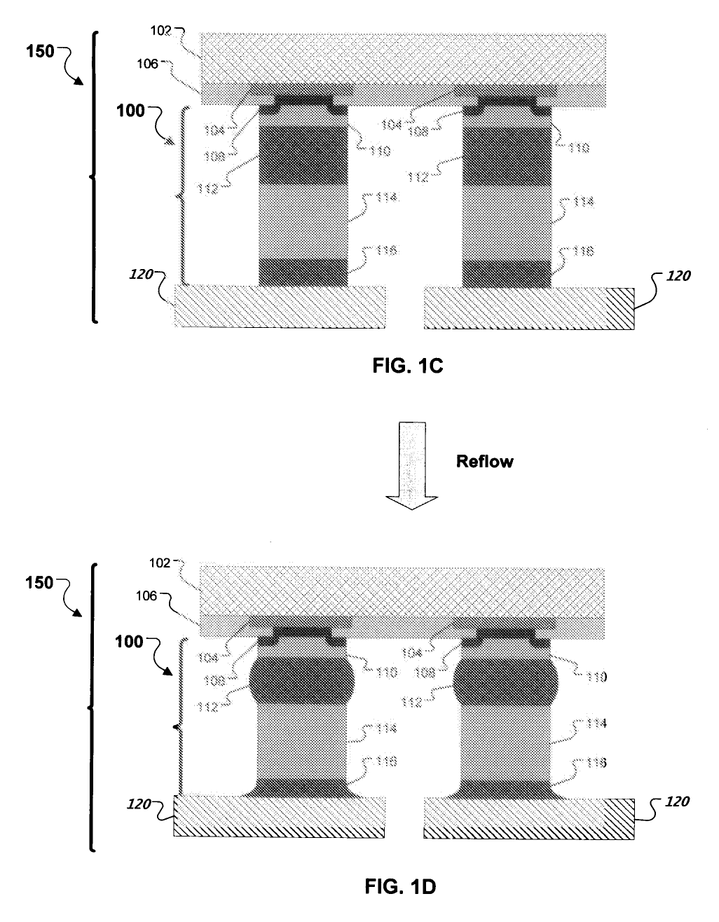

FIG. 1A is a cross-sectional diagram of a flip-chip interconnect structure 100 having a stress relief means. As noted above, the flip-chip interconnect structure 100 can be used to connect a semiconductor chip 102 to a supporting substrate (not shown). The semiconductor chip 102 can have one or more bond pads 104 that provide electrical connection from the semiconductor chip 102 to other devices through the flip-chip interconnect structure 100. The semiconductor chip 102 can also have a protective and stress relief layer 106 (e.g., a dielectric film) that can serve as a passivation layer for protecting the surface of the semiconductor chip 102 and absorbing stress from the flip-chip interconnect structure 100. A seed layer 108 (e.g., a under bump metallization layer) can be used to, e.g., improve the adhesion of the flip-chip interconnect structure 100 to the bond pads 104. In addition, the seed layer 108 can be used as a diffusion barrier to prevent inter-metallic diffusion between the flip-chip-interconnect structure 100 and the bond pads 104. In other implementations, the seed layer 108 can be part of the flip-chip interconnect structure 100.

The flip-chip interconnect structure 100 can be pillar shaped (e.g., circular or rectangular) and include a series of layers that are reflowable and non-reflowable at a predetermined elevated temperature. For example, suppose that the non-reflowable layer (or layers) consists of copper and/or nickel material and that the reflowable layer consists of a eutectic lead/tin solder material. At a predetermined elevated reflow temperature of around 210° C., the eutectic lead/tin solder starts to melt and reflows into a different shape (e.g., a ball), while the non-reflowable layer does not melt and stays in solid form. In general, whether a layer is characterized as a reflowable layer or a non-reflowable layer can depend on the predetermined elevated temperature. As a result, in one implementation a layer consisting of a particular material may be characterized as a non-reflowable layer; however, in another implementation, that same material can form a layer that can be characterized as a reflowable layer because the predetermined elevated temperature has increased.

For example, suppose that a first flip-chip interconnect structure includes a layer consisting of tin, which has a melting temperature of about 231° C., and a layer consisting of indium, which has a melting temperature of about 156° C. Because the solder reflow temperature can typically be about 10 to 30 degrees higher than the melting temperature, at a predetermined elevated temperature of about 170° C., the layer consisting of indium will start to reflow and change its shape, whereas the layer consisting of tin will not reflow. Therefore, in the first flip-chip interconnect structure the layer consisting of tin can be characterized as the non-reflowable layer, and the layer consisting of indium can be characterized as the reflowable layer.

On the other hand, suppose that a second flip-chip interconnect structure includes a layer consisting of tin and a layer consisting of copper, which has a melting temperature substantially higher than that of tin. At a predetermined reflow temperature of about 245° C. (which is about 10 to 30 degrees higher than the melting temperature), the layer consisting of tin will start to reflow and change its shape, whereas the layer consisting of copper will not reflow. Therefore, in the second flip-chip interconnect structure the layer consisting of copper can be characterized as the non-reflowable layer, and the layer consisting of tin (which can be characterized as the non-reflowable layer in the first flip-chip interconnect structure) can be characterized as the reflowable layer.

As shown in FIG. 1A, the flip-chip interconnect structure 100 includes a non-reflowable base layer 110 that contacts the bond pads 104 of the semiconductor 102 via the seed layer 108. The non-reflowable base layer 110 can include, e.g., one or more metal layers consisting of copper, nickel, tin, and any suitable alloy thereof (e.g., tin-bismuth, tin-copper, or tin-silver). In certain implementations, the non-reflowable base layer 110 is made of copper. In one implementation, the non-reflowable base layer 110 is a non-elongated copper layer with a dimension of, e.g., less than 25 microns thick and between about 50 to 250 microns in width or diameter. Additionally, as noted above, the shape of the flip-chip interconnect structure 100 can be circular, octagonal, rectangular, or any other shape.

The flip-chip interconnect structure 100 additionally includes a reflowable stress relief layer 112 disposed on the non-reflowable base layer 110. The reflowable stress relief layer 112 can include, e.g., solder material consisting of tin, indium, tin-lead alloy, tin-bismuth alloy, tin-copper alloy, tin-silver alloy, and any suitable ternary alloys thereof (e.g., tin-silver-copper alloy). In certain implementations, the reflowable stress relief layer 112 is a tin solder layer. As discussed above, the reflowable stress relief layer 112 has a melting temperature about 10 to 30 degrees lower than a predetermined reflow temperature of the solder. In certain implementations, the amount of solder deposited for the reflowable stress relief layer 112 is between about 25 to 50 microns thick.

The flip-chip interconnect structure 100 also includes a non-reflowable body layer 114, which can, e.g., serve as the main or elongated portion of the flip-chip interconnect structure 100. The non-reflowable body layer 114 is disposed on the reflowable stress relief layer 112. The non-reflowable body layer 114 can include, e.g., one or more metal layers consisting of copper, nickel, tin, and any suitable alloy thereof (e.g., tin-bismuth, tin-copper, or tin-silver). In certain implementations, the body layer 114 is made of copper. In one implementation, the body layer 114 and the base layer 110 can be made of the same metal material; for example, both non-reflowable layers 110 and 114 can be copper metal layers.

In another implementation, the material for the body layer 114 can be different from the base layer 110; for example, the body layer 114 can be a copper metal layer while the base layer 110 can be a nickel metal layer. As an example, the elongated non-reflowable body layer 114 can have a thickness or height of between about 50 to 100 microns and a width or diameter of between about 50 to 250 microns. Additionally, as noted above, the shape of the pillar for the flip-chip interconnect structure 100 can be circular, octagonal, rectangular, or any other shape.

The flip-chip interconnect structure 100 also includes a reflowable fusing layer 116 that is disposed on the non-reflowable body layer 114. The reflowable fusing layer 116 can include, e.g., solder material consisting of tin, indium, tin-lead alloy, tin-bismuth alloy, tin-copper alloy, tin-silver alloy, and any suitable ternary alloys thereof (e.g., tin-silver-copper alloy). In certain implementations, the reflowable fusing layer 116 is a tin solder layer. Additionally, both the reflowable fusing layer 116 and the reflowable stress relief layer 112 can be made of the same solder material and be reflowed at the same predetermined reflow temperature. In certain implementations, the amount of solder deposited for the reflowable fusing layer 116 is between about 15 to 35 microns thick.

In this manner, as shown in FIG. 1B, after an optional reflow process prior to flip-chip assembly, the flip-chip interconnect structure 100 can have a slightly different shape because the solder reflows at the reflow temperature. For example, depending on the amount of solder material, the reflowable fusing layer 116 can have a hemispherical or a spherical shape after reflow. In addition, the reflowable stress relief layer 112 can have a pancake shape after reflow. As noted above, one of the potential advantages of the flip-chip interconnect structure 100 is that wafer level reflow is an optional process and is not required prior to forming the flip-chip assembly.

In some implementations, the reflowable stress relief layer 112 can be designed to have a higher reflow temperature than the reflowable fusing layer 116. In this manner, the flip chip interconnect structure 100 can be reflowed (at the higher reflow temperature) at wafer level to first produce a controlled collapse of the reflowable stress relief layer 112. Additionally, although the reflowable fusing layer 116 also reflows at the higher temperature, because the amount of solder used for the reflowable fusing layer 116 can be less, it does not reflow very much. Thus, the reflowable fusing layer 116 of a flip chip assembly can be reflowed at a second temperature (which is lower than the first temperature and does not reflow the stress relief layer 112) to join the semiconductor chip 102 to the supporting substrate.

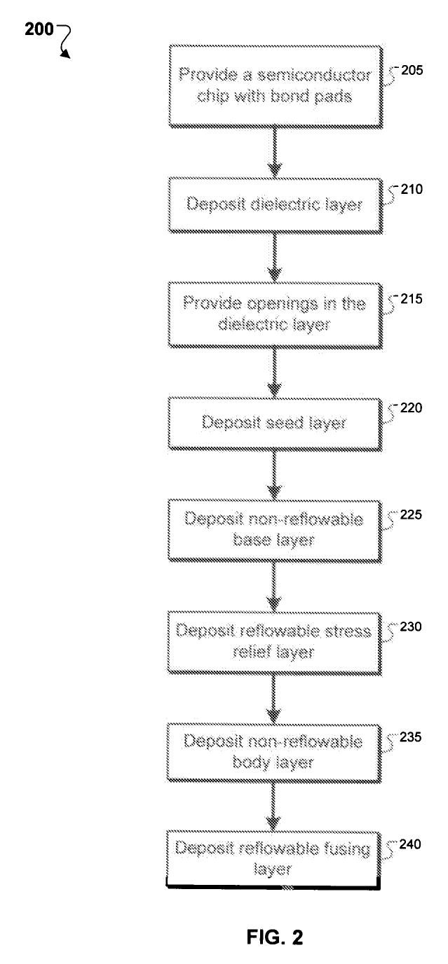

FIG. 1C is a cross-sectional diagram showing a flip-chip assembly 150 including the semiconductor chip 102, the flip-chip interconnect structure 100, and metal interconnects 120 of a supporting substrate prior to reflow. Once the flip-chip interconnect structure 100 is provided, the semiconductor chip 102 can then be flipped and dipped in a solder flux prior to the formation of the flip chip assembly. The solder flux can be used to remove oxides on the metal interconnects 120 of a circuit substrate and improve bonding of the solder. In one implementation, the flip-chip interconnect structure 100 is dipped in a flux bath so that only the fusing layer 116 is immersed in the flux. Details of how the flip-chip interconnect structure 100 can be provided will be discussed further below in FIG. 2.

FIG. 1D is a cross-sectional diagram showing the flip-chip assembly 150 after reflow. As discussed above, the reflow temperature of the flip chip assembly 150 can be a predetermined elevated temperature that depends on the composition of the reflowable stress relief layer 112 and the reflowable fusing layer 116. For example, suppose that both the reflowable stress relief layer 112 and the reflowable fusing their 116 are made of tin solder. The reflow temperature for the flip chip assembly 150 will be about 245° C. because of the tin solder. As shown in FIG. 1D, for the flip-chip assembly 150 after reflow, the reflowable fusing layer 116 of the interconnect structure 100 has been fused with the metal interconnects 120.

Additionally, the reflowable stress relief layer 112 is sandwiched between the base layer 110 and the elongated body layer 114. In one implementation, interconnect structure 100 can have more than one reflowable stress relief layers 112. For example, additional non-reflowable body layers 114 can be inserted between the one or more reflowable stress relief layers 112. In this manner, the reflowable stress relief layers 112 can be replaced by a sandwiched structure including a series of reflowable stress relief layers 112+non-reflowable body layer 114+reflowable stress relief layers 112+non-reflowable body layer 114+reflowable stress relief layers 112, and so on. In certain implementations, each layer (e.g., the reflowable layer or the non-reflowable layer) of the interconnect structure 100 can include one or more layers. For example, the reflowable stress relief layer 112 can include a first layer consisting of a first material (e.g., tin), a second layer consisting of a second material (e.g., indium), a third layer consisting of a third material (e.g., bismuth) or even the first material, and so on.

The flip-chip interconnect structure 100 can be designed to withstand the mechanical shearing stresses that are developed by temperature fluctuations and the difference in thermal expansion coefficients between the semiconductor chip 102 and the supporting circuit substrate during operation of the semiconductor chip 102. For example, when the semiconductor chip 102 and the supporting substrate are exposed to elevated temperatures, they can expand at different rates and to different dimensions, thereby inducing mechanical stresses in the flip-chip interconnect structure 100.

By incorporating one or more reflowable stress relief layers 112 the flip-chip interconnect structure 100 can essentially have a shock absorbing means to accommodate the thermally-induced mechanical stresses. This is because the stress relief layer 112 can reduce the rigidity of the interconnect structure 100 and function as a flexible member in order to absorb the applied mechanical stresses. Additionally, the aspect ratio (i.e., the ratio of the height over the diameter) of the interconnect structure can be increased to further increase the shock absorbing means of the stress relief layer 112. Further, as discussed above, the flip chip interconnect structure 100 can have a controlled collapse after reflow because no solder dams are needed to prevent solder overrun and help shape the solder.

In addition, the reflowable stress relief layer 112 can be designed so that the reflowed solder of the stress relief layer 112 does not reflow substantially into the adjacent non-reflowable body layer 114 and non-reflowable base layer 110. For example, there is likely oxide formation (e.g., copper oxide due to oxidation) on the side walls of the non-reflowable base layer 110 and the non-reflowable body layer 114. Furthermore, the contact angle between the reflowed solder of the stress relief layer 112 in the adjacent non-reflowable layers is approximately 180° and there is virtually no wetting angle for the reflowed solder. In addition, in contrast to the reflowable fusing layer 116, the reflowed solder of the stress relief layer 112 will not have flux during reflow. Because of all these reasons, the reflowed solder of the stress relief layer 112 can be prevented from overrunning into the adjacent non-reflowable layers (110 and 114).

FIG. 2 is a flow chart showing an example process 200 of providing a flip-chip interconnect structure having a stress relief means. In general, the illustrated process involves depositing a series of reflowable and non-reflowable layers on top of the bond pads of a semiconductor chip. As described above, the flip-chip interconnect structure can include a non-reflowable base layer that contacts the bond pads on the semiconductor chip, an elongated non-reflowable body layer, a reflowable stress relief layer sandwiched between the non-reflowable base layer and the non-reflowable body layer, and a reflowable fusing layer that contacts the metal interconnects on the supporting substrate.

In this example implementation, process 200, at 205, provides a semiconductor chip with bond pads, which can be, e.g., aluminum, gold, copper pads. In contrast to wire bonding, the flip-chip assembly uses the electrical connection of a face-down semiconductor chip onto a supporting substrate by means of conductive interconnects formed on the bond pads of the semiconductor chip. At 210, process 200 deposits a dielectric layer on the surface of the semiconductor chip. The dielectric layer can be, e.g., a silicon dioxide, silicon nitride, polyimide, a BCB film, or any combination thereof. The dielectric layer can be used as a passivation layer for protecting the surface of the semiconductor chip and as a stress buffer layer for preventing stress from penetrating into silicon. Deposition of the dielectric layer can be by a spin-on process or any suitable chemical vapor deposition process.

At 215, process 200 provides openings in the dielectric layer to expose a portion of the bond pads on the semiconductor chip. This step can be performed by a photolithographic process for patterning, e.g. a photoresist layer, and then etching the dielectric layer (e.g., in a plasma reactor) through the openings of the patterned photoresist. Alternatively, a photo-definable dielectric layer (e.g., Polyimide or BCB) can be used to define the pattern and form the opening. In one implementation, the passivation process (e.g., step 215 of process 200) can include (1) deposit SiO and Nitride, (2) spin on photo-definable polyimide, (3) perform photolithography process to open polyimide, and (4) use the pattered polyimide as a mask to dry etch the SiO/Nitride passivation film.

Once the bond pads have been opened, at 220, process 200 deposits the seed layer for the flip-chip interconnect structure, e.g., by sputtering, thermal evaporation, and the like. Additionally, process 200 can prepare the flip-chip interconnect sites on the bond pads of the semiconductor chip by cleaning, removing insulating oxides, and providing a pad metallurgy that will protect the semiconductor chip while making a good mechanical and electrical connection to the solder bump and the supporting structure.

The seed layer can generally include successive layers of metal, such as adhesion layer and diffusion barrier layer. For example, the adhesion layer can adhere well to both the bond pad metal and the surrounding dielectric layer, and provide a strong, low-stress mechanical and electrical connection. The diffusion barrier layer can limit the diffusion of solder into the underlying material. In one implementation, a titanium- or chromium-based film can be used as the adhesion layer and a nickel- or tungsten-based film can be used as the diffusion barrier layer. In certain implementations, Ti/W/Cu or Ti/Cu alloy is used as the seed layer. In addition, the seed layer can be sputtered or evaporated over the entire surface of the semiconductor chip, providing a good conduction path for the electroplating currents.

At 225, process 200 deposits the non-reflowable base layer of the flip-chip interconnect structure, e.g., by electroplating. As noted above, the non-reflowable base layer can include, e.g., one or more metal layer consisting of copper, nickel, tin, and any suitable alloy thereof (e.g., tin-bismuth, tin-copper, or tin-silver). In certain implementations, copper is deposited as the non-reflowable base layer. As an example, process 210 can deposit the non-reflowable base layer to form a non-elongated metal layer with a dimension of, e.g., less than 25 microns thick and between about 50 to 250 microns in diameter. In one implementation, process 210 can deposit copper as the non-reflowable base layer by electroplating. Electroplating of the non-reflowable base layer can be a less costly and more flexible process than evaporation. Plating bath solutions and current densities can be carefully controlled to avoid variations in alloy composition and copper thickness or height across the semiconductor chip.

At 230, process 200 deposits the reflowable stress relief layer of the flip-chip interconnect structure, e.g., by electroplating. The reflowable stress relief layer can include, e.g., solder material consisting of tin, indium, tin-lead alloy, tin-bismuth alloy, tin-copper alloy, tin-silver alloy, and any suitable ternary alloys thereof (e.g., tin-silver-copper alloy). In certain implementations, tin is deposit as the reflowable stress relief layer of the flip chip interconnect structure. In addition, the reflowable stress relief layer reflows at a predetermined elevated temperature, which corresponds to the reflow temperature of the solder and can be about 10 to 30 degrees higher than the melting temperature of the solder.

In one implementation, the amount of solder (e.g., thickness) deposited for the reflowable stress relief layer can be predetermined based on the layer structure and the overall geometry of the flip-chip interconnect structure. For example, the thickness of the stress relief layer can be a percentage of the thickness of the non-reflowable body layer. In this manner, the stress relief layer can have sufficient material to function as a shock absorber for the induced mechanical stresses. In certain implementations, the amount of solder deposited for the reflowable stress relief layer is between about 25 to 50 microns thick.

After the reflowable stress relief layer has been deposited, at 235, process 200 deposits the non-reflowable body layer of the flip-chip interconnect structure, e.g., by electroplating. The non-reflowable body layer can serve as the main or elongated portion of the flip-chip interconnect structure. Additionally, the non-reflowable body layer can include, e.g., one or more metal layer consisting of copper, nickel, tin, and any suitable alloy thereof (e.g., tin-bismuth, tin-copper, or tin-silver). In certain implementations, process 200 electroplates copper as the elongated reflowable body layer with a thickness of between about 50 to 75 microns and a width or diameter of between about 50 to 250 microns.

At 240, process 200 deposits the reflowable fusing layer of the flip-chip interconnect structure, e.g., by electroplating. The reflowable fusing layer can include, e.g., solder material consisting of tin, indium, tin-lead alloy, tin-bismuth alloy, tin-copper alloy, tin-silver alloy, and any suitable ternary alloys thereof (e.g., tin-silver-copper alloy). In addition, the reflowable fusing layer melts at a predetermined elevated temperature, which corresponds to the reflow temperature of the solder. In one implementation, both the reflowable fusing layer and the reflowable stress relief layer can be made of the same solder material and be reflowed at the same reflow temperature.

The amount of solder for the reflowable fusing layer can be predetermined so that a substantial portion of the reflowable fusing layer can remain at the interconnect locations (e.g., metal interconnects 120 of FIG. 1B) during reflow when the solder is in molten state. In certain implementations, the amount of solder deposited for the reflowable fusing layer is between about 15 to 35 microns thick. In this manner, the problem of solder overrun can be avoided and solder dams do not have to be used. For example, an electroplating process can allow the amount of solder deposited to be better controlled and more uniform on the semiconductor chip. The amount of solder used for the reflowable fusing layer can depend on a variety of factors which can include: type of solder, dimensions of the non-reflowable body layer, material at the interconnect location, mass of the semiconductor die, number of copper posts, reflow profile when reflowing the solder, the expected final dimensions of the reflowed solder and copper post, and the type of flux.

While this specification contains many specific implementation details, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

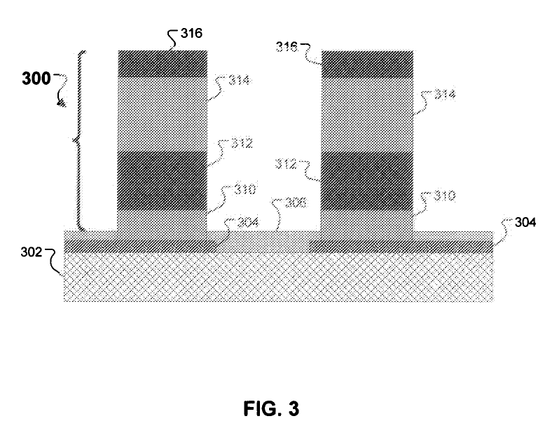

A number of embodiments have been described. Nevertheless, it will be understood that various modifications may be made without departing from the spirit and scope of the described embodiments. For example, FIG. 3 is a cross-sectional diagram of a flip-chip interconnect structure having a stress relief means disposed on a supporting or interconnection substrate, instead of the semiconductor chip. As described above, the flip-chip interconnect structure 300 can be used to connect a semiconductor chip (not shown) to a supporting substrate 302. The supporting substrate 302 can have one or more metal interconnects 304 that provide electrical connection from the supporting substrate 302 to other devices. The supporting substrate 302 also has a protective layer 306 (e.g., a dielectric film) that serves as a solder mask layer for protecting the surface of the supporting substrate 302.

As shown in FIG. 3, the flip-chip interconnect structure 300 includes a non-reflowable base layer 310 that contacts the metal interconnects 304 of the supporting substrate 302. In certain implementations, the non-reflowable base layer 310 is made of copper. For example, the non-reflowable base layer 310 can be a non-elongated metal layer with a dimension of, e.g., less than 10 microns thick and between about 50 to 250 microns in width or diameter. Details of how the flip-chip interconnect structure 300 can be provided has been discussed further above in FIG. 2. Accordingly, other embodiments are within the scope of the following claims.

What is claimed is:

1. A flip-chip assembly comprising:
a semiconductor work piece;
a plurality of interconnect structures connected to the semiconductor work piece, each of the interconnect structures comprising:
a first non-reflowable metal layer in contact with the semiconductor work piece;
a second non-reflowable metal layer; and
at least one reflowable stress relief layer that reflows at a predetermined first reflow temperature;
wherein the reflowable stress relief layer is between the first and the second non-reflowable metal layers.

2. The flip-chip assembly of claim 1, wherein the first non-reflowable layer has a first melting temperature higher than the predetermined first reflow temperature, and wherein the second non-reflowable layer has a second melting temperature higher than the predetermined first reflow temperature.

3. The flip-chip assembly of claim 2, wherein the first melting temperature is the same as the second melting temperature.

4. The flip-chip assembly of claim 1, wherein the predetermined first reflow temperature is about 10 to 30 degrees higher than a melting temperature of the reflowable stress relief layer.

5. The flip-chip assembly of claim 1, further comprising a supporting substrate, wherein each of the interconnect structures further comprising a reflowable fusing layer, connected to the supporting substrate, that reflows at a predetermined second reflow temperature.

6. The flip-chip assembly of claim 5, wherein the predetermined first reflow temperature is the same as the predetermined second reflow temperature.

7. The flip-chip assembly of claim 5, wherein the predetermined first reflow temperature is higher than the predetermined second reflow temperature, such that the reflowable stress relief layer does not reflow at the predetermined second reflow temperature.

8. The flip-chip assembly of claim 1, wherein the first and the second non-reflowable metal layers each comprises copper, nickel, or tin.

9. The flip-chip assembly of claim 1, wherein the second non-reflowable metal layer is thicker than the first non-reflowable metal layer.

10. The flip-chip assembly of claim 1, wherein the reflowable stress relief layer comprises either tin, indium, tin-lead alloy, tin-bismuth alloy, tin-copper alloy, tin-silver alloy, or tin-silver-copper alloy.

11. A method of providing a flip-chip interconnect structure, the method comprising:
providing a semiconductor work piece that includes one or more bond pads;
depositing a first non-reflowable layer that has a first melting temperature higher than a predetermined first reflow temperature;
depositing a reflowable stress relief layer that reflows at the predetermined first reflow temperature; and
depositing a second non-reflowable layer that has a second melting temperature higher than the predetermined first reflow temperature such that the deposited reflowable stress relief layer is between the first and the second non-reflowable layers.

12. The method of claim 11, wherein the predetermined first reflow temperature is about 10 to 30 degrees higher than a melting temperature of the reflowable stress relief layer.

13. The method of claim 11, further comprising:
depositing a reflowable fusing layer that reflows at a predetermined second reflow temperature.

14. The method of claim 13, wherein the predetermined first reflow temperature is the same as the predetermined second reflow temperature.

15. The method of claim 13, wherein the predetermined first reflow temperature is higher than the predetermined second reflow temperature, such that the reflowable stress relief layer does not reflow at the predetermined second reflow temperature.

16. The method of claim 13, wherein the deposited reflowable stress relief layer is thicker than the deposited reflowable fusing layer.

17. The method of claim 11, further comprising:
patterning a dielectric layer with openings for the one or more bond pads; and
depositing a seed layer on each of the bond pads.

18. The method of claim 17, wherein the deposited first non-reflowable layer is above the deposited seed layer.

19. The method of claim 11, wherein the first melting temperature is the same as the second melting temperature.

20. The method of claim 11, wherein the deposited second non-reflowable metal layer is thicker than the deposited first non-reflowable metal layer.

21. The method of claim 11, wherein the first and second non-reflowable metal layers each comprises copper, nickel, or tin.

22. The method of claim 11, wherein the deposited reflowable stress relief layer comprises either tin, indium, tin-lead alloy, tin-bismuth alloy, tin-copper alloy, tin-silver alloy, or tin-silver-copper alloy.

23. A flip-chip assembly comprising:
a semiconductor work piece;
a plurality of interconnect structures connected to the semiconductor work piece, each of the interconnect structures comprising:
a first non-reflowable metal layer in contact with the semiconductor work piece;
a second non-reflowable metal layer; and
means for providing a stress relief to the interconnect structure.

24. The flip-chip assembly of claim 23, wherein the stress relief means comprises a reflowable stress relief layer that reflows at a predetermined first reflow temperature further comprising; and each of the interconnect structures further comprising a reflowable fusing layer that reflows at a predetermined second reflow temperature.

25. The flip-chip assembly of claim 24, wherein the predetermined first reflow temperature is higher than the predetermined second reflow temperature, such that the reflowable stress relief layer does not reflow at the predetermined second reflow temperature.
